(19) United States
(12) Patent Application Publication
(10) Pub. No.: US 2014/0060629 A1
(43) Pub. Date: Mar. 6, 2014

(54) SOLAR CELL AND METHOD FOR FABRICATING THE SAME

(71) Applicant: AU Optronics Corp., Hsin-Chu (TW)

(72) Inventors: Liang-Hsing Lai, Hsin-Chu (TW); Chih-Cheng Lu, Hsin-Chu (TW); Jen-Chieh Chen, Hsin-Chu (TW); Zhen-Cheng Wu, Hsin-Chu (TW)

(73) Assignee: AU Optronics Corp., Hsin-Chu (TW)

(21) Appl. No.: 13/961,886

(22) Filed: Aug. 8, 2013

(30) Foreign Application Priority Data
Sep. 5, 2012 (CN) 201210326717.6

(51) Int. Cl. H01L 31/0256; H01L 31/0236

(52) U.S. Cl. CPC H01L 31/0256; H01L 31/02366
USPC 136/255; 438/87

(57) ABSTRACT

A solar cell includes a substrate, a first lightly-doped region, a second lightly-doped region, a second heavily-doped region, a first electrode and a second electrode. The first lightly-doped region having a first doping type is disposed in a first surface of the substrate. The second lightly-doped region and the second heavily-doped region having a second doping type different from the first doping type are disposed in a second surface of the substrate. The first electrode is disposed on the first surface of the substrate, and the second electrode is disposed on the second surface of the substrate.

### BACKGROUND OF THE DISCLOSURE

1. Field of the Disclosure

The present disclosure relates to a solar cell and a fabricating method thereof, and more particularly, to a solar cell with selective back surface field (selective BSF) and a fabricating method thereof.

2. Description of the Prior Art

As our natural resources set to decline rapidly, a solar cell which converts the solar energy directly into electrical energy is the most potential alternative energy. However, current solar technology is still limited by several obstacles such as high production cost, complicated process, and low photo-electric conversion efficiency. Therefore, fabricating low production cost, simple process, and high photo-electric conversion efficiency solar cell to replace the conventional high-pollution and high-risk energy is a main objective in the field.

### SUMMARY OF THE DISCLOSURE

It is one of the objectives of the disclosure to provide a solar cell with high photo-electric conversion efficiency and its fabricating method.

To achieve the purposes described above, an embodiment of the disclosure provides a method for fabricating solar cell. The method comprises the following steps. First, a substrate is provided, which has a first surface and a second surface opposite to the first substrate. A first lightly-doped region in the first surface of the substrate is formed. A second lightly-doped region and a second heavily-doped region are formed in the second surface of the substrate, wherein the second lightly-doped region and the second heavily-doped region have a second doped type different from the first doped type. A first electrode is formed on the first surface of the substrate. A second electrode is formed on the second surface of the substrate.

To achieve the purposes described above, another embodiment of the disclosure provides the solar cell. The solar cell comprises a substrate, a first lightly-doped region, a second lightly-doped region, a second heavily-doped region, a first electrode, and a second electrode. The substrate has a first surface and a second surface, wherein the first surface is a light incident plane and the second surface is opposite to the first surface. The first lightly-doped region is disposed in the first surface of the substrate and has a first doped type. The second lightly-doped region and the second heavily-doped region are disposed in the second surface of the substrate and have a second doped type different from the first doped type. A first electrode is disposed on the first surface of the substrate. A second electrode is disposed on the second surface of the substrate.

The back surface field structure of the solar cell in the present disclosure has two kinds of doping concentration, and therefore can effectively increase the photo-electric conversion efficiency.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic diagrams illustrating the method for fabricating a solar cell according to a first embodiment of this disclosure.

FIGS. 7-10 are schematic diagrams illustrating the method for fabricating the solar cell according to a variant embodiment of the first embodiment of this disclosure.

FIG. 11 is a comparison diagram illustrating the open circuit voltage (Voc) of the solar cells according to the first embodiment and the comparative embodiment of this disclosure.

FIG. 12 is a comparison diagram illustrating the photo-electric conversion efficiency of the solar cells according to the first embodiment and the comparative embodiment of this disclosure.

FIG. 13 is a schematic diagram illustrating a solar cell according to a second embodiment of this disclosure.

FIG. 14 is a schematic diagram illustrating the solar cell according to a third embodiment of this disclosure.

FIG. 15 is a schematic diagram illustrating the solar cell according to a fourth embodiment of this disclosure.

### DETAILED DESCRIPTION

To provide a better understanding of the present disclosure, the embodiments will be made in detail. The embodiments of the present disclosure are illustrated in the accompanying drawings with numbered elements. In addition, the terms such as “first” and “second” described in the present disclosure are used to distinguish different components or processes, which do not limit the sequence of the components or processes.

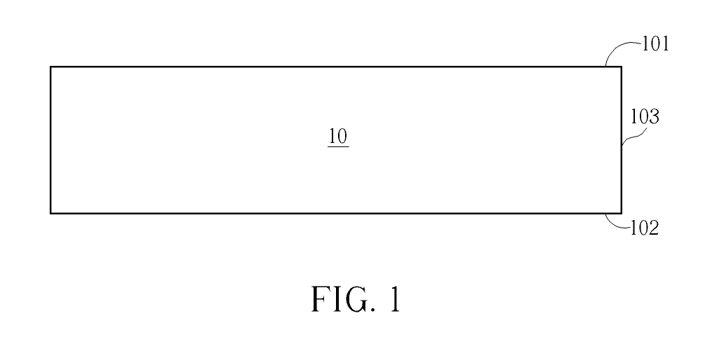

Please refer to FIGS. 1-6. FIGS. 1-6 are schematic diagrams illustrating the method for fabricating a solar cell according to a first embodiment of this disclosure. As shown in FIG. 1, a substrate 10 is provided first. The substrate 10 is a silicon substrate, which may be, for example, a single crystalline silicon substrate, a polycrystalline silicon substrate, a microcrystalline silicon substrate or a nanocrystalline silicon substrate, but not limited thereto. The substrate 10 may be any other kinds of semiconductor substrates. The substrate 10 has a first surface 101 and a second surface 102 opposite to the first substrate 101, and the first surface 101 is the light incident plane. A saw damage removal (SDR) process is then performed on the substrate 10: cleaning the substrate 10 with, for instance, acidic or Alkaline solution to remove slight damage on the substrate 10.

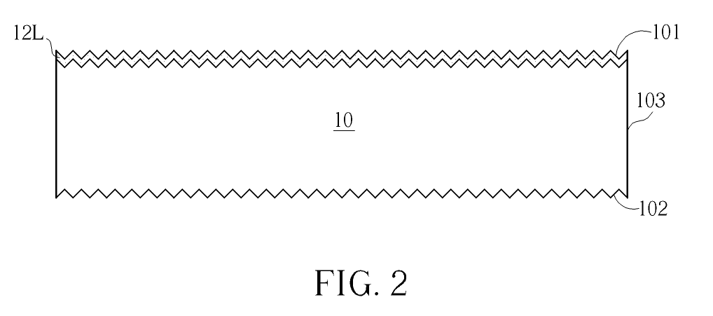

As shown in FIG. 2, a texturing process is carried out to make the first surface 101 and/or the second surface 102 of the substrate 10 have a textured surface, therefore increasing the incident light intensity. The texturing process may be formed by a dry etching process, or a wet etching process. The textured surface is formed by many micro-structures such as pyramid structures, and the height of each micro-structure is substantially 0.1 micrometer (um)-0.15 um, but not limited thereto. Furthermore, a first lightly-doped region 12L is formed in the first surface 101 of the substrate 10, wherein the first lightly-doped region 12L has a first doped type and the substrate 10 has a second doped type. The first doped type is different from the second doped type; for example, the first doped type may be n-type, and the second doped type may be p-type, but not limited thereto. The doping concentration of the first lightly-doped region 12L is substantially 1*10¹⁹ atom/cm³-1*10²¹ atom/cm³, for example, 2*10²⁰ atom/cm³, but not limited thereto. The sheet resistance of the first lightly-doped region 12L is substantially 80Ω/□-120Ω/□(Ω/square), for example, 90Ω/□(Ω/square), but not limited thereto. In this embodiment, the first lightly-doped region may be formed by a diffusion process. For example, if the first doped type is n-type, the dopant for the diffusion process may be phosphorous, arsenic, antimony, or compounds thereof; if the first doped type is p-type, the dopant for the diffusion process may be boron or boron compounds. After the diffusion process, an edge isolation process is carried out to remove the doped layer formed at the edge 103 between the first surface 101 and the second surface 102 of the substrate 10 in the diffusion process, and to ensure the first surface 101 and the second surface 102 of the substrate 10 to be electrically isolated. The edge isolation process may be a laser cutting process, a dry etching process, or a wet etching process, for example. The method of forming the first lightly-doped region 12L is not limited by a diffusion process, and in this embodiment, the first lightly-doped region 12L can also be formed by an ion implantation process.

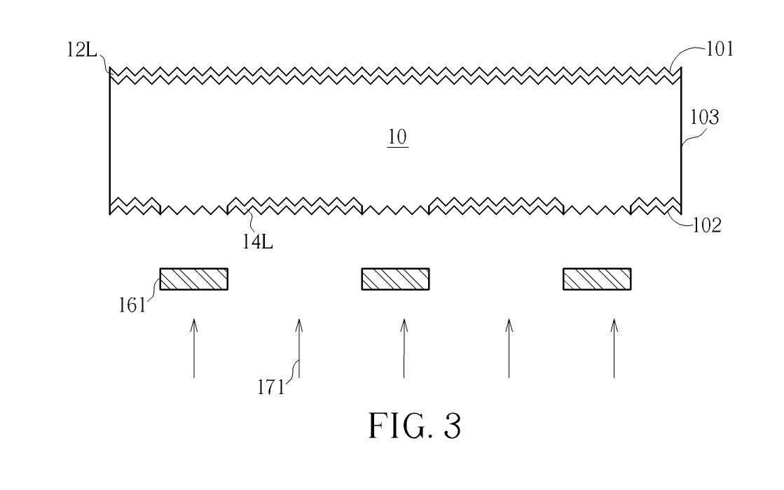

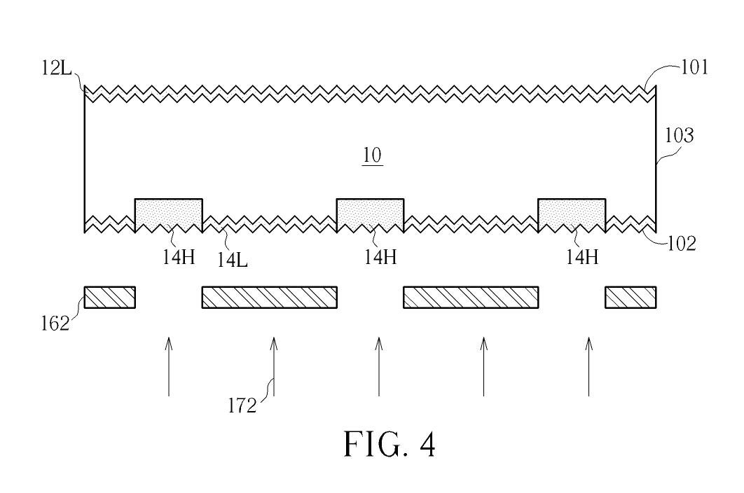

A second lightly-doped region 14L and a second heavily-doped region 14H are then formed in the second surface 102 of the substrate 10, wherein the second lightly-doped region 14L and the second heavily-doped region 14H have a second doped type. In this embodiment, the second lightly-doped region 14L is disposed in a portion of the second surface 102 of the substrate 10, and the second heavily-doped region 14H is disposed in the other portion of the second surface 102 of the substrate 10; in other words, the second lightly-doped region 14L does not overlap the second heavily-doped region 14H in a vertical projection direction. In this embodiment, the method to form the second lightly-doped region 14L and the second heavily-doped region 14H in the second surface 102 of the substrate 10 is as follows. As shown in FIG. 3, a first ion implantation process 171 with a first mask 161 is carried out to form the second lightly-doped region 14L in the portion of the second surface 102 of the substrate 10 without shielded by the first mask 161. As shown in FIG. 4, a second ion implantation process 172 with a second mask 162 is carried out to form the second heavily-doped region 14H in the other portion of the second surface 102 of the substrate 10 without shielded by the second mask 162. In this embodiment, the doping concentration of the second lightly-doped region 14L is substantially 1*10¹⁷ atom/cm³-5*10¹⁸ atom/cm³, for example, 3*10¹⁸ atom/cm³, and the doping concentration of the second heavily-doped region 14H is substantially 5*10¹⁸ atom/cm³-1*10¹⁹ atom/cm³, for example, 6*10¹⁸ atom/cm³, but not limited thereto. The sheet resistance of the second lightly-doped region 14L is substantially 50Ω/□-80Ω/□(Ω/square), for example, 60Ω/□(Ω/square), and the sheet resistance of the second heavily-doped region 14H is substantially 20Ω/□-50Ω/□(Ω/square), for example, 30Ω/□(Ω/square), but not limited thereto. Moreover, the order of forming the second lightly-doped region 14L and the second heavily-doped region 14H may be rearranged. In this embodiment, the second lightly-doped region 14L and the second heavily-doped region 14H form the patterned back surface field (patterned BSF), and area ratio of the second lightly-doped region 14L to the second heavily-doped region 14H is substantially 1:1 to 20:1, but not limited thereto.

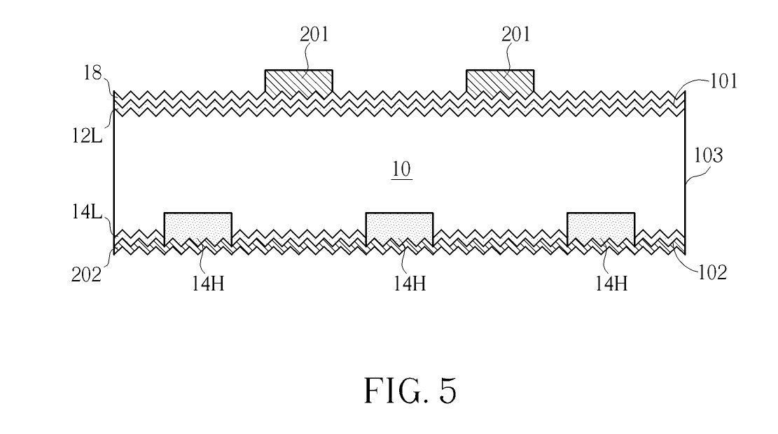

As shown in FIG. 5, an anti-reflection layer 18 is formed on the first surface 101 of the substrate 10. In this embodiment, the anti-reflection layer 18 is formed conformally on the first surface 101 of the substrate 10; therefore, the anti-reflection layer 18 has the texture surface. The anti-reflection layer 18 can increase the amount of incident light. The anti-reflection layer 18 may be a single or multiple layer structure, but not limited thereto. The material of the anti-reflection layer 18 may be silicon nitride, silicon oxide, silicon oxynitride, or other appropriate material, but not limited thereto. The anti-reflection layer 18 may be formed by a plasma-enhanced chemical vapor deposition (PECVD) process, for example, but not limited thereto. A first electrode 201 is then formed on the first surface 101 of the substrate 10, and a second electrode 202 is formed on the second surface 102 of the substrate 10. The second electrode 202 is in contact with both the second lightly-doped region 14L and the second heavily-doped region 14H. The first electrode 201 may be a single or multiple layer structure for the finger electrode of the solar cell. The material of the first electrode 201 may be high conductivity material, such as silver (Ag), but not limited thereto, which may be other high conductivity material, such as gold (Au), aluminum (Al), copper (Cu), or stannum (Sn). The second electrode 202 may be a single or multiple layer structure, and the second electrode 202 is the back electrode for the solar cell. The material of the second electrode 202 may be high conductivity material, such as silver (Ag), but not limited thereto, which may be other high conductivity material, such as gold (Au), aluminum (Al), copper (Cu), or stannum (Sn). In this embodiment, the first electrode 201 and the second electrode 202 are preferably formed by printing processes, respectively. The material of the first electrode 201 and the second electrode 202 may be conductive paste, for instance, conductive paste with silver or aluminum, but not limited thereto.

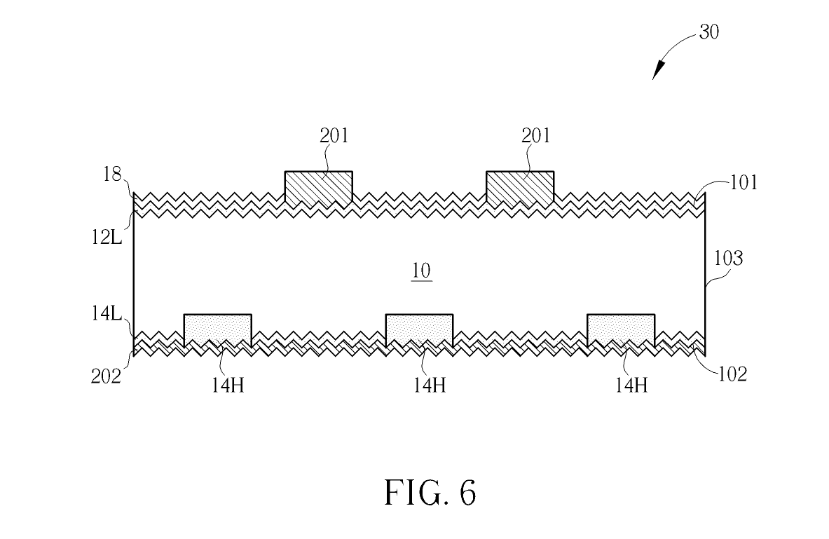

As shown in FIG. 6, a sintering process is performed to make the first electrode 201 penetrate the anti-reflection layer 18, and therefore in contact with and electrically connected to the lightly-doped region 12L. The solar cell 30 of this embodiment is completed.

Methods of fabricating solar cell are not restricted to the preceding embodiments. Other solar cells and other feasible methods for fabricating the solar cell will be disclosed in the following paragraphs. For brevity purposes, like or similar features in multiple embodiments will usually be described with similar reference numerals for ease of illustration and description thereof.

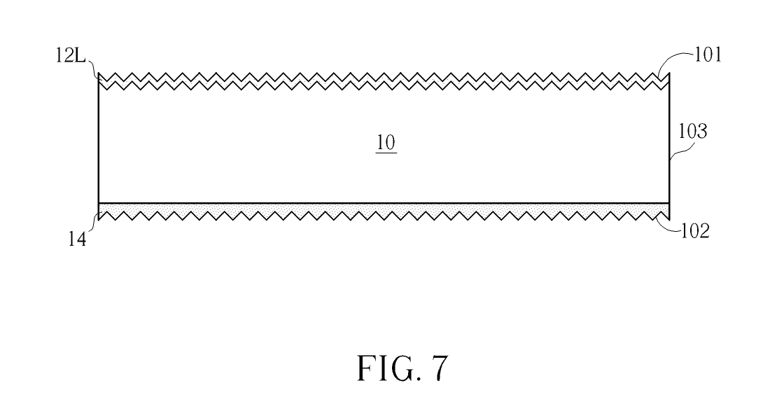

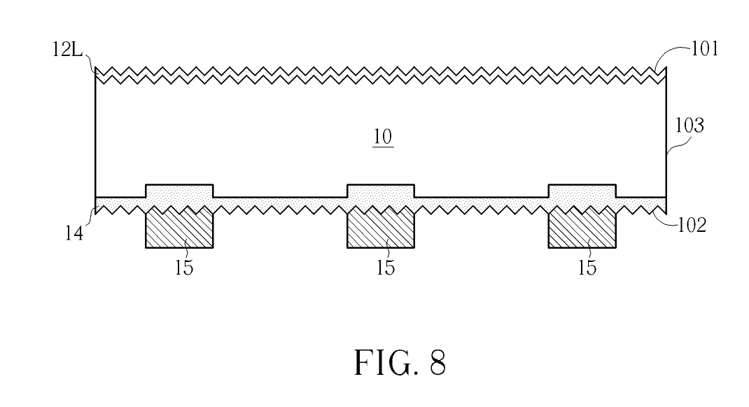

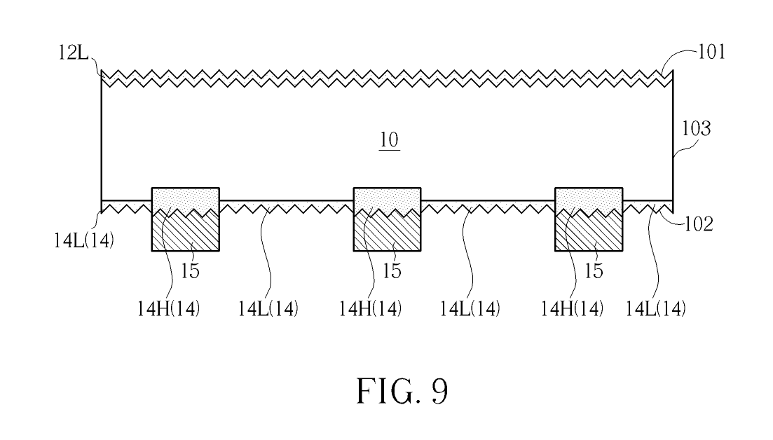

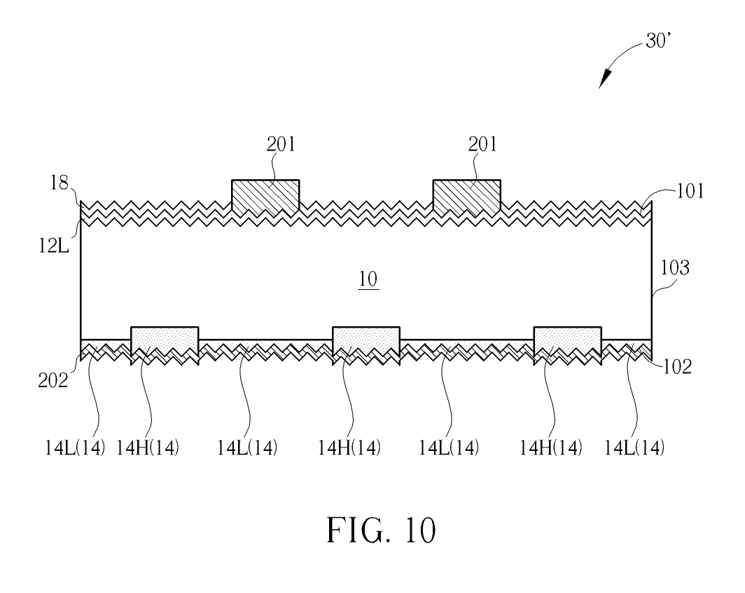

Please refer to FIGS. 7-10 and FIGS. 1-2. FIGS. 7-10 are schematic diagrams illustrating the method for fabricating the solar cell according to the variant embodiment of the first embodiment of this disclosure. The method for fabricating the solar cell of this variant embodiment continues from the step of FIG. 2 of the first embodiment. The main difference between this variant embodiment and the first embodiment is the steps to form the second lightly-doped region 14L and the second heavily-doped region 14H. As shown in FIG. 7, a heavily-doped region 14 is formed entirely in the second surface 102 of the substrate 10, and the heavily-doped region 14 has the second doped type. The heavily-doped region 14 may be formed by a diffusion process or an ion implantation process, for example. As shown in FIG. 8, a patterned mask layer 15 is formed on the second surface 102 of the substrate 10. The patterned mask layer 15 shields a portion of the second surface 102 of the substrate 10 and exposes a portion of the second surface 102 of the substrate 10. To be more specific, the patterned mask layer 15 exposes a portion of the heavily-doped region 14. The pattern mask layer 15 may be formed on the second surface 102 of the substrate 10 by an ink jet printing process, but not limited thereto. The material of the pattern mask layer 15 can be, for example, paraffin, but not limited thereto. Thermal treatment, for example, an annealing process is then performed on the substrate 10. Because the pattern mask layer 15 has a higher thermal conductivity coefficient, the dopant in the portion of the heavily-doped region 14 shielded by the pattern mask layer 15 may diffuse deeply into the substrate 10 such that the depth of the heavily-doped region 14 shielded by the pattern mask layer 15 is deeper than the depth of the heavily-doped region 14 not shielded by the pattern mask layer 15. As shown in FIG. 9, a portion of the heavily-doped region 14 exposed by the patterned mask layer 15 is removed to form the second lightly-doped region 14L. The step to remove the portion of the heavily-doped region 14 exposed by the patterned mask layer 15 may be a wet etching process such as immersing the substrate 10 into acid liquor to remove the portion of the heavily-doped region 14 exposed by the patterned mask layer 15 and to form the second lightly-doped region 14L, or a dry etching process such as a reactive ion etching (RIE) process to remove the portion of the heavily-doped region 14 exposed by the patterned mask layer 15 and to form the second lightly-doped region 14L, but not limited thereto. As shown in FIG. 10, the patterned mask layer 15 is removed to expose the heavily-doped region 14 shielded by the patterned mask layer 15. Because a portion of the dopant in the heavily-doped region 14 exposed by the pattern mask layer 15 is removed, the doping concentration in the heavily-doped region 14 after the removing treatment will be lower than the original doping concentration of the heavily-doped region 14, which is doped heavily. Moreover, the doping concentration in the heavily-doped region 14 shielded by the pattern mask layer 15 remains the same as the original and thus the second heavily-doped region 14H is formed. The anti-reflection layer 18 is formed on the first surface 101 of the substrate 10. The first electrode 201 is formed on the first surface 101 of the substrate 10, and a second electrode 202 is formed on the second surface 102 of the substrate 10. The sintering process is performed to make the first electrode 201 penetrate the anti-reflection layer 18, and therefore in contact with and electrically connected to the first lightly-doped region 12L. The solar cell 30 of this embodiment is completed.

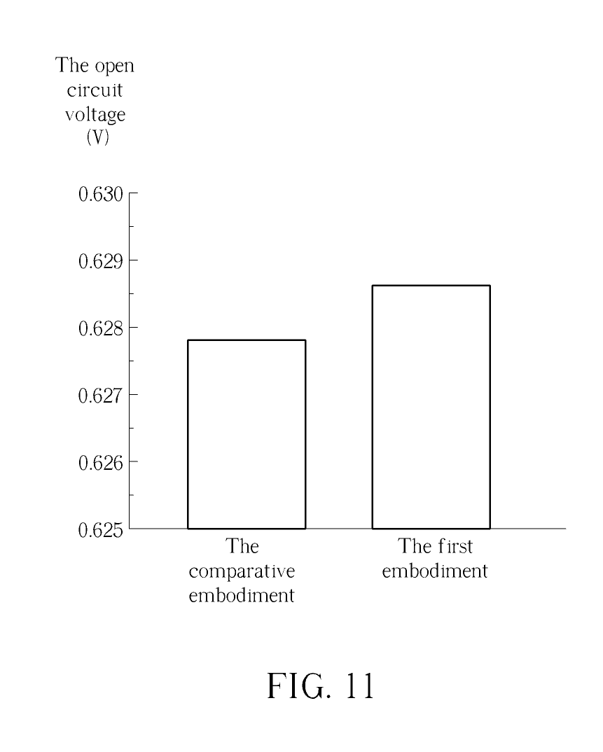

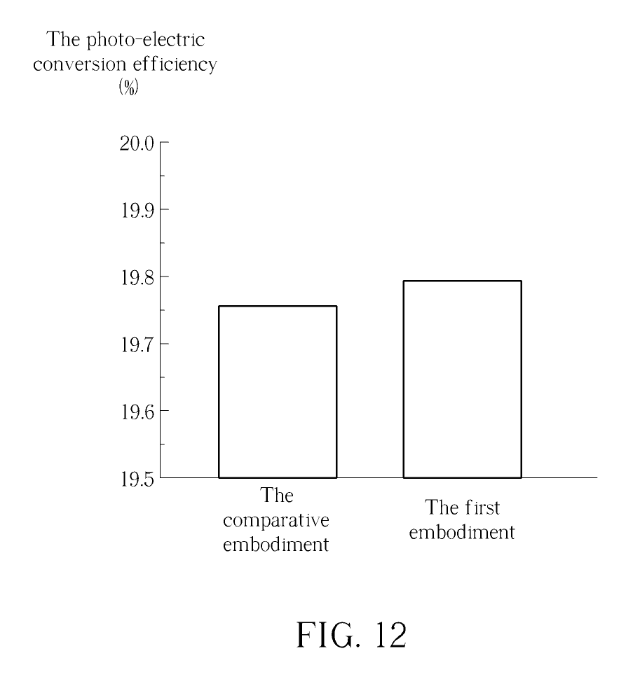

Please refer to FIGS. 11-12 and FIG. 6. FIG. 11 is a comparison diagram illustrating the open circuit voltage (Voc) of the solar cells according to the first embodiment and the comparative embodiment of this disclosure. FIG. 12 is a comparison diagram illustrating the photo-electric conversion efficiency of the solar cells according to the first embodiment and the comparative embodiment of this disclosure. The above-mentioned open circuit voltage (Voc) and the above-mentioned photo-electric conversion efficiency of the solar cells are simulated using the conditions listed in Table 1 below.

TABLE 1

| | | The |
|---|---|---|
| | The first | comparative |
| | embodiment | embodiment |
| Surface recombination velocity (cm/s) | 10⁶ | 10⁶ |
| The lifetime of the electron-hole pairs in the | 100 | 100 |
| substrate (μs) | | |
| The doping concentration of the substrate | 7.2 * 10¹⁵ | 7.2 * 10¹⁵ |
| (atom/cm³) | | |
| The doping concentration of the first lightly- | 2 * 10²⁰ | 2 * 10²⁰ |
| doped region (atom/cm³) | | |
| The doping concentration of the second | 3 * 10¹⁸ | 3 * 10¹⁸ |
| lightly-doped region (atom/cm³) | | |
| The doping concentration of the second | 6 * 10¹⁸ | NA |
| heavily-doped region (atom/cm³) | | |
| The sheet resistance of the second lightly- | 30 | 30 |
| doped region (Ω/□) (or Ω/square) | | |
| The sheet resistance of the second heavily- | 15 | NA |
| doped region (Ω/□) (or Ω/square) | | |
| The area ratio of the second lightly-doped | 1:1 | NA |
| region and the second heavily-doped region | | |

The solar cell in this embodiment has the patterned back surface field structure with two kinds of doping concentration—lightly-doping and heavily-doping concentration—while the solar cell in the comparative embodiment only has the patterned back surface field structure with one doping concentration. As shown in FIG. 11, the open circuit voltage of the solar cell in this embodiment is approximately 0.6285V, and the open circuit voltage of the solar cell in the comparative embodiment is approximately 0.6275V. As shown in FIG. 12, the photo-electric conversion efficiency of the solar cell in this embodiment is approximately 19.8%, and the photo-electric conversion efficiency of the solar cell in the comparative embodiment is approximately 19.74%. From the above simulation results, the patterned back surface field structure of the solar cell in this embodiment can enhance the open circuit voltage (Voc) and the photo-electric conversion efficiency of the solar cell effectively.

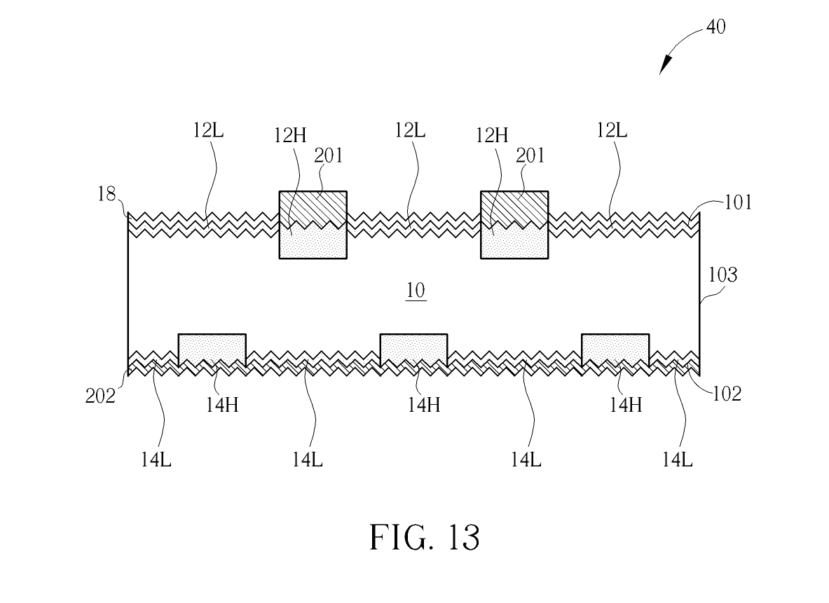

Please refer to FIG. 13. FIG. 13 is a schematic diagram illustrating a solar cell according to a second embodiment of this disclosure. As shown in FIG. 13, the solar cell 40 in this embodiment, different from the first embodiment, further comprises a first heavily-doped region 12H disposed in the first surface 101 of the substrate 10. The first heavily-doped region 12H has the first doped type, and the doping concentration in the first heavily-doped region 12H is higher than the doping concentration in the first lightly-doped region 12L. Furthermore, the first electrode 201 is formed on the first heavily-doped region 12H, and the first electrode 201 is in contact with and electrically connected to the first heavily-doped region 12H to form a selective emitter structure. In this embodiment, the method to form the first lightly-doped region 12L and the first heavily-doped region 12H may be an ion implantation process with a mask, and this method is similar to the method of forming the second lightly-doped region 14L and the second heavily-doped region 14H in the first embodiment. In the variant embodiment, the method to form the first lightly-doped region 12L and the first heavily-doped region 12H may be a diffusion process or an ion implantation process with a etching process, and this method is similar to the method of forming the second lightly-doped region 14L and the second heavily-doped region 14H in the variant embodiment of the first embodiment.

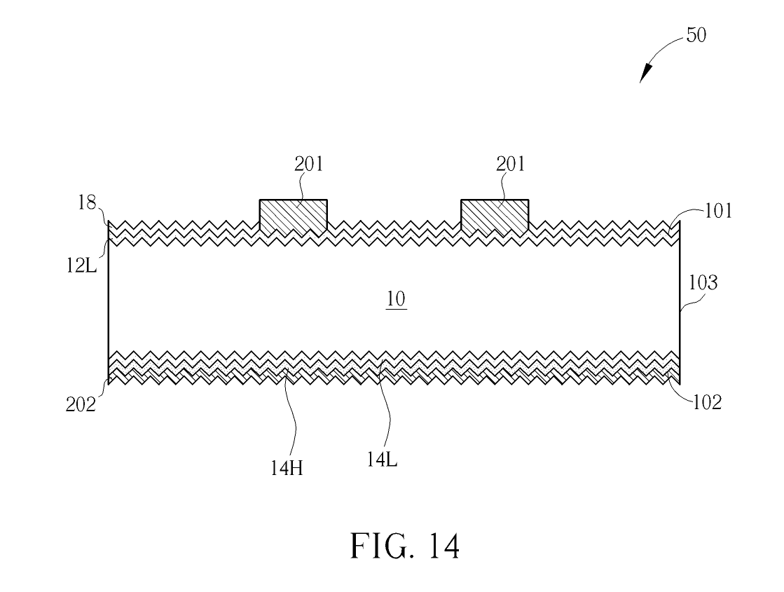

Please refer to FIG. 14. FIG. 14 is a schematic diagram illustrating a solar cell according to a third embodiment of this disclosure. As shown in FIG. 14, in the solar cell 50 of this embodiment, different from the solar cell 30 of the first embodiment, the second lightly-doped region 14L is disposed in the second surface 102 of the substrate 10, the second heavily-doped region 14H is disposed on the second lightly-doped region 14L, the second electrode 202 is in contact with and electrically connected to the second heavily-doped region 14H. The second lightly-doped region 14L and the second heavily-doped region 14H can be formed by a diffusion process or an ion implantation process in order, but not limited thereto. Moreover, the location of the second lightly-doped region 14L and the second lightly-doped region 14H can be changed.

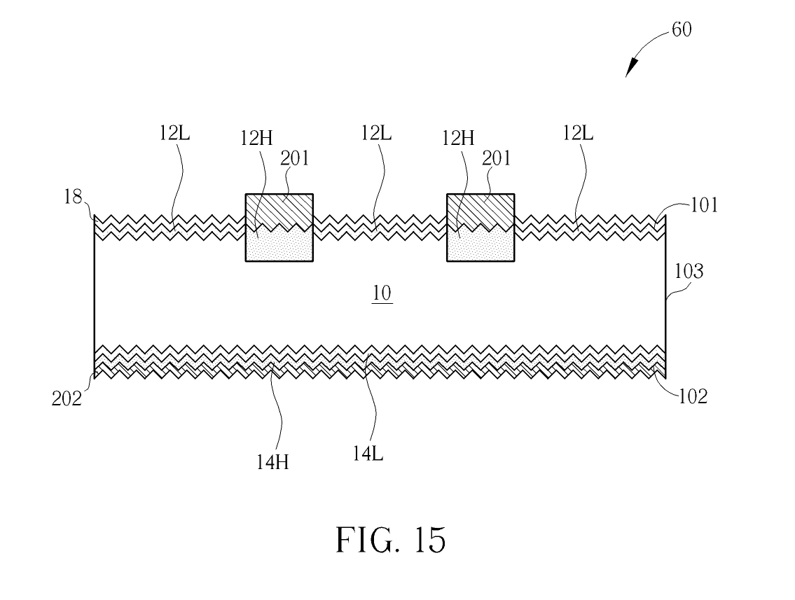

Please refer to FIG. 15. FIG. 15 is a schematic diagram illustrating a solar cell according to a fourth embodiment of this disclosure. As shown in FIG. 15, in the solar cell 60 of this embodiment, different from the solar cell 40 of the second embodiment, the second lightly-doped region 14L is disposed in the second surface 102 of the substrate 10, the second heavily-doped region 14H is disposed on the second lightly-doped region 14L, the second electrode 202 is in contact with and electrically connected to the second heavily-doped region 14H. The second lightly-doped region 14L and the second heavily-doped region 14H can be formed by a diffusion process or an ion implantation process in order, but not limited thereto. Moreover, the location of the second lightly-doped region 14L and the second lightly-doped region 14H can be changed.

To sum up, the back surface field structure of the solar cell in the present disclosure is formed by the second lightly-doped region and the second heavily-doped region. The second lightly-doped region has a lower saturation current, and therefore the recombination of electron-hole pair reduces. Moreover, the second lightly-doped region can increase blue response, and therefore increases the close circuit current. The second heavily-doped region is heavily doped; therefore the contact resistance between the second electrode and the second heavily-doped region is lower and the fill factor can increase. The second heavily-doped region increases Fermi level difference, and therefore increases the open circuit voltage and the photo-electric conversion efficiency. From the simulation result, the back surface field structure of the solar cell in the present disclosure has two kinds of doping concentration, and can effectively increase the photo-electric conversion efficiency.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for fabricating a solar cell, which comprises:
providing a substrate, which has a first surface and a second surface opposite to the first surface;
forming a first lightly-doped region in the first surface of the substrate, wherein the first lightly-doped region has a first doped type;
forming a second lightly-doped region and a second heavily-doped region in the second surface of the substrate, wherein the second lightly-doped region and the second heavily-doped region have a second doped type different from the first doped type;
forming a first electrode on the first surface of the substrate; and
forming a second electrode on the second surface of the substrate.

2. The method for fabricating the solar cell of claim 1, wherein the substrate has the second doped type.

3. The method for fabricating the solar cell of claim 1, wherein the second lightly-doped region is disposed in a portion of the second surface of the substrate, the second heavily-doped region is disposed in the other portion of the second surface of the substrate, and the second electrode is in contact with and electrically connected to both the second lightly-doped region and the second heavily-doped region.

4. The method for fabricating the solar cell of claim 3, wherein the step of forming the second lightly-doped region comprises:
performing a first ion implantation process with a first mask to form the second lightly-doped region in the substrate without shielded by the first mask; and
the step of forming the second heavily-doped region comprises:
performing a second ion implantation process with a second mask to form the second heavily-doped region in the substrate without shielded by the second mask.

5. The method for fabricating the solar cell of claim 3, wherein the step of forming the second lightly-doped region and the second heavily-doped region comprises:
forming a heavily-doped region entirely in the second surface of the substrate;
forming a patterned mask layer on the second surface of the substrate, wherein the patterned mask layer shields a portion of the second surface of the substrate and exposes a portion of the heavily-doped region;
removing a portion of the heavily-doped region exposed by the patterned mask layer to form the second lightly-doped region; and
removing the patterned mask layer to expose the heavily-doped region shielded by the patterned mask layer and to form the second heavily-doped region.

6. The method for fabricating the solar cell of claim 1, wherein the second lightly-doped region is disposed in the second surface of the substrate, the second heavily-doped region is disposed on the second lightly-doped region, and the second electrode is in contact with and electrically connected to the second heavily-doped region.

7. The method for fabricating the solar cell of claim 1, further comprising performing a texturing process to make the first surface of the substrate have a textured surface.

8. The method of fabricating the solar cell of claim 1, further comprising forming an anti-reflection layer on the first surface of the substrate.

9. The method for fabricating the solar cell of claim 1, further comprising forming a first heavily-doped region on the first surface of the substrate and forming the first electrode on the first heavily-doped region, wherein the first heavily-doped region has the first doped type and the first electrode is in contact with and electrically connected to the first heavily-doped region.

10. A solar cell, which comprises:
a substrate, which has a first surface and a second surface, wherein the first surface is a light incident plane and the second surface is opposite to the first surface;
a first lightly-doped region disposed in the first surface of the substrate, wherein the first lightly-doped region has a first doped type;
a second lightly-doped region disposed in the second surface of the substrate;
a second heavily-doped region disposed in the second surface of the substrate, wherein the second lightly-doped region and the second heavily-doped region have a second doped type different from the first doped type;
a first electrode disposed on the first surface of the substrate; and
a second electrode disposed on the second surface of the substrate.

11. The solar cell of claim 10, wherein the substrate has the second doped type.

12. The solar cell of claim 10, wherein the second lightly-doped region is disposed in a portion of the second surface of the substrate, the second heavily-doped region is disposed in the other portion of the second surface of the substrate, and the second electrode is in contact with and electrically connected to both the second lightly-doped region and the second heavily-doped region.

13. The solar cell of claim 10, wherein the second lightly-doped region is disposed in the second surface of the substrate, the second heavily-doped region is disposed on the second lightly-doped region, and the second electrode is in contact with and electrically connected to the second heavily-doped region.

14. The solar cell of claim 10, wherein the first surface of the substrate is a textured surface.

15. The solar cell of claim 10, further comprising an anti-reflection layer disposed on the first surface of the substrate.

16. The solar cell of claim 10, further comprising a first heavily-doped region disposed in the first surface of the substrate, wherein the first heavily-doped region has the first doped type, the first electrode is formed on the first heavily-doped region and the first electrode is in contact with and electrically connected to the first heavily-doped region.
